(19) United States
(12) Patent Application Publication
(10) Pub. No.: US 2012/0214272 A1
(43) Pub. Date: Aug. 23, 2012

(54) METHOD OF MANUFACTURING ORGANIC THIN FILM SOLAR CELL

(76) Inventors: Tsukasa Azuma, Kawasaki-Shi (JP); Ikuo Yoneda, Yokohama-Shi (JP); Akiko Mimotogi, Yokohama-Shi (JP); Ryoichi Inanami, Yokohama-Shi (JP); Mitsunaga Saito, Inzai-Shi (JP); Hiroki Iwanaga, Yokohama-Shi (JP); Akiko Hirao, Kawasaki-Shi (JP)

(21) Appl. No.: 13/231,453

(22) Filed: Sep. 13, 2011

(30) Foreign Application Priority Data
Feb. 22, 2011 (JP) 2011-036224

(51) Int. Cl. H01L 31/18

(52) U.S. Cl. 438/82; 257/E31.032

(57) ABSTRACT

Certain embodiments provide a method of manufacturing an organic thin film solar cell comprising forming, on a first electrode, a first transport layer having an uneven pattern and a photoelectric conversion layer provided on a surface of the uneven pattern, forming a second transport layer on a second electrode, and bringing the uneven pattern having the photoelectric conversion layer is formed thereon into contact with the second transport layer to mold the second transport layer.

### CROSS REFERENCE TO RELATED APPLICATION

This application is based upon and claims benefit of priority from the Japanese Patent Application No. 2011-36224, filed on Feb. 22, 2011, the entire contents of which are incorporated herein by reference.

1. Field

Embodiments described herein relate generally to a method of manufacturing an organic thin film solar cell.

2. Background

In recent years, an organic thin film solar cell has been drawing attention as one type of next-generation solar cell. In the organic thin film solar cell, when incident light is applied, excitons (pairs of electrons and holes) are generated in a photoelectric conversion layer (organic semiconductor). When charge separation of the excitons occurs, the electrons and holes move to an electron transport layer and a hole transport layer between which the photoelectric conversion layer is placed.

In such an organic thin film solar cell, it is possible to enhance the photoelectric conversion efficiency by increasing the contact areas (interface areas) of the electron transport layer, the hole transport layer, and the photoelectric conversion layer. Therefore, it is demanded to manufacture, at low cost, the organic thin film solar cell with large contact areas of the electron transport layer, the hole transport layer, and the photoelectric conversion layer.

### BRIEF DESCRIPTION OF THE DRAWINGS

FIG. 1A is a process cross-sectional view for explaining a method of manufacturing an organic thin film solar cell according to an embodiment of the present invention;

FIG. 1B is a process cross-sectional view subsequent to FIG. 1A;

FIG. 1C is a process cross-sectional view subsequent to FIG. 1B;

FIG. 1D is a process cross-sectional view subsequent to FIG. 1C;

FIG. 2A is a process cross-sectional view subsequent to FIG. 1D;

FIG. 2B is a process cross-sectional view subsequent to FIG. 2A;

FIG. 2C is a process cross-sectional view subsequent to FIG. 2B;

FIG. 2D is a process cross-sectional view subsequent to FIG. 2C;

FIG. 3A is a process cross-sectional view for explaining a method of manufacturing an organic thin film solar cell according to a first modification;

FIG. 3B is a process cross-sectional view subsequent to FIG. 3A;

FIG. 3C is a process cross-sectional view subsequent to FIG. 3B;

FIG. 4A is a process cross-sectional view for explaining a method of manufacturing an organic thin film solar cell according to another modification;

FIG. 4B is a process cross-sectional view subsequent to FIG. 4A;

FIG. 5A is a process cross-sectional view for explaining a method of manufacturing an organic thin film solar cell according to a second modification;

FIG. 5B is a process cross-sectional view subsequent to FIG. 5A;

FIG. 5C is a process cross-sectional view subsequent to FIG. 5B;

FIG. 5D is a process cross-sectional view subsequent to FIG. 5C;

FIG. 6A is a process cross-sectional view for explaining a method of manufacturing an organic thin film solar cell according to a third modification;

FIG. 6B is a process cross-sectional view subsequent to FIG. 6A;

FIG. 6C is a process cross-sectional view subsequent to FIG. 6B;

FIG. 6D is a process cross-sectional view subsequent to FIG. 6C;

FIG. 7A is a process cross-sectional view for explaining a method of manufacturing an organic thin film solar cell according to another modification; and

FIG. 7B is a process cross-sectional view subsequent to FIG. 7A.

### DETAILED DESCRIPTION

Certain embodiments provide a method of manufacturing an organic thin film solar cell comprising forming, on a first electrode, a first transport layer having an uneven pattern and a photoelectric conversion layer provided on a surface of the uneven pattern, forming a second transport layer on a second electrode, and bringing the uneven pattern having the photoelectric conversion layer is formed thereon into contact with the second transport layer to mold the second transport layer.

Embodiments will now be explained with reference to the accompanying drawings.

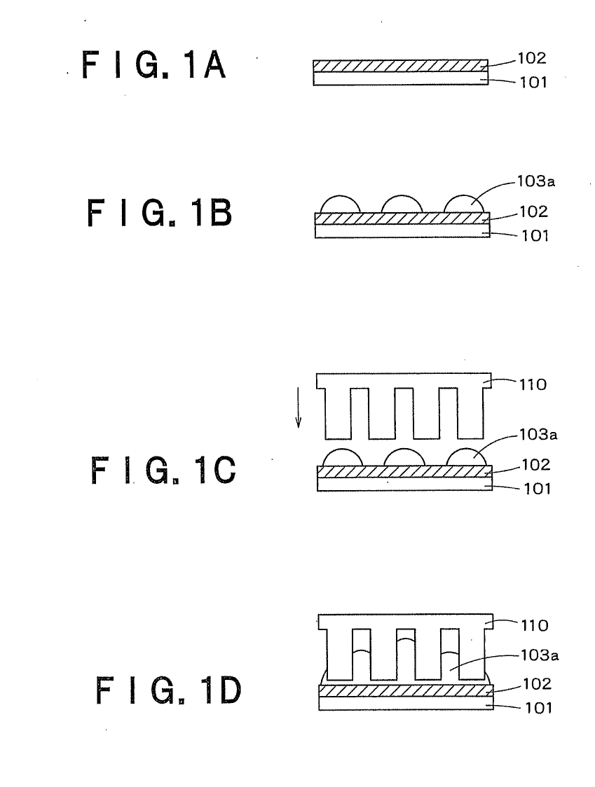

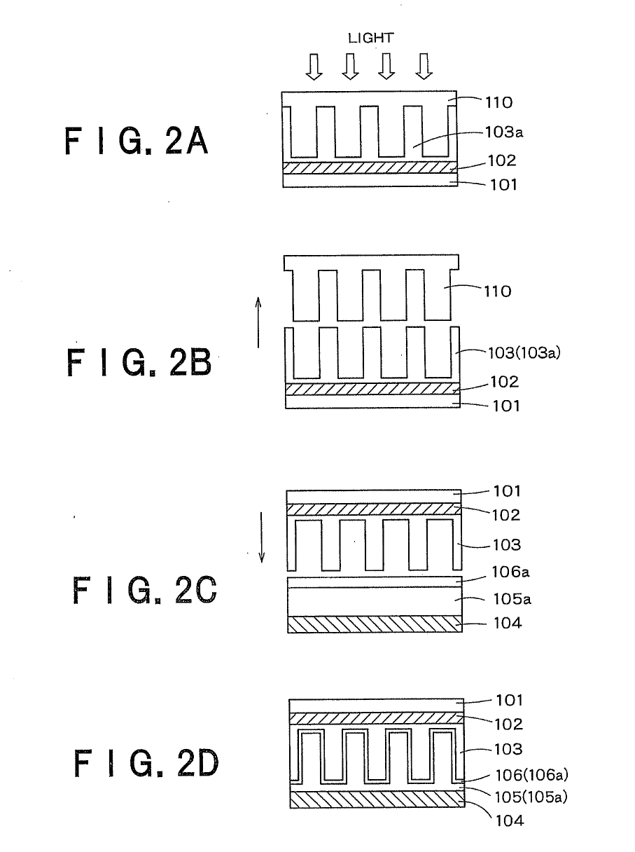

Descriptions will now be made to a method of manufacturing an organic thin film solar cell according to an embodiment of the present invention, using the process cross-sectional views shown in FIGS. 1A to 1D and 2A to 2D.

As illustrated in FIG. 1A, indium tin oxide (ITO) having a thickness of about 150 nm is sputtered on a glass substrate 101, thereby forming a transparent electrode 102 with sheet resistance 10 Ω/□.

As illustrated in FIG. 1B, a liquid hole transport layer formation material 103a is applied over the transparent electrode 102. The hole transport layer formation material 103a includes a material for forming a hole transport layer 103 (as will be described later), such as PEDOT/PSS
(poly(3,4-ethylenedioxythiophene)/poly(4-styrenesulfonic acid)). The hole transport layer formation material 103a has photo-curing property.

As illustrated in FIG. 1C, a template 110 is brought into contact with the hole transport layer formation material 103a. The template 110 is, for example, formed to have an uneven (a concave-convex) pattern on an all-transparent quartz substrate (for use, in general, as a photo mask) using a plasma etching technique.

If the template 110 is brought into contact with the hole transport layer formation material 103a, the liquid hole transport layer formation material 103a flows into the uneven pattern of the template 110, as illustrated in FIG. 1D.

As illustrated in FIG. 2A, after the uneven pattern of the template 110 is filled with the hole transport layer formation material 103a, incident light (UV light) is applied to harden the hole transport layer formation material 103a.

As illustrated in FIG. 2B, the template 110 is separated from the hole transport layer formation material 103a. In this state, the hole transport layer formation material 103a has already been hardened, thus maintaining the state (form) in which the template 110 has come into contact therewith. This results in forming the hole transport layer 103 having an uneven patterned surface.

As illustrated in FIG. 2C, an electron transport layer formation material 105a with a thickness of about 10 nm is formed on a metal electrode 104 which is made from aluminum. The electron transport layer formation material 105a includes a material, such as titanium oxide (TiOx), included in an electro transport layer 105 that will be described later.

Further, a photoelectric conversion layer formation material 106a with a thickness of about 100 nm is formed on the electron transport layer formation material 105a. The photoelectric conversion layer formation material 106a is included in a photoelectric conversion layer 106 that will be described later, and includes a compound of a p-type organic semiconductor and an n-type organic semiconductor. Typical materials for p-type organic semiconductors include polymeric organic semiconductors, such as P3HT, PCDTBT, and PTB7. Typical materials for N-type organic semiconductors include C60, C70, PC61BM, and PC71BM.

Both of the electron transport layer formation material 105a and the photoelectric conversion layer formation material 106a are photo-curing and thermal-curing materials.

A laminated body is composed of the glass substrate 101, the transparent electrode 102, and the hole transport layer 103 which are made in the step illustrated in FIG. 2B. The laminated body is brought into contact with another laminated body composed of the metal electrode 104, the electron transport layer formation material 105a, and the photoelectric conversion layer formation material 106a. At this time, the uneven patterned surface of the hole transport layer 103 is pushed into the photoelectric conversion layer formation material 106a and the electron transport layer formation material 105a.

As illustrated in FIG. 2D, the photoelectric conversion layer formation material 106a and the electron transport layer formation material 105a go into the uneven pattern of the hole transport layer 103. The uneven pattern is filled with the photoelectric conversion layer formation material 106a and the electron transport layer formation material 105a. Subsequently, light irradiation or heating is performed to harden the photoelectric conversion layer formation material 106a and the electron transport layer formation material 105a. This results in forming the electron transport layer 105 having the uneven patterned surface. The photoelectric conversion layer 106 is formed in a position between the uneven patterned surface of the hole transport layer 103 and the uneven patterned surface of the electron transport layer 105.

Accordingly, the organic thin film solar cell shown in FIG. 2D can be obtained. In this solar cell, the metal electrode 104, the electron transport layer 105, the photoelectric conversion layer 106, the hole transport layer 103, the transparent electrode 102, and the glass substrate 101 are laminated sequentially in this order. In this organic thin film solar cell, excitons are generated in the photoelectric conversion layer 106, when incident light is applied to the photoelectric conversion layer 106 through the glass substrate 101, the transparent electrode 102, and the hole transport layer 103. When charge separation of the excitons occurs, the electrons move to the electron transport layer 105, while the holes move to the hole transport layer 103.

In this embodiment, contact interfaces between the hole transport layer 103, the electron transport layer 105, and the photoelectric conversion layer 106 are uneven. As compared to the case in which the contact interfaces are evenly flat, the contact areas (interface areas) increase. Thus, the photoelectric conversion efficiency can be enhanced.

In this embodiment, the hole transport layer 103 with an uneven structure is formed using the template 110 based on an imprint process. After that, the electron transport layer 105 and the photoelectric conversion layer 106 are simultaneously molded using the template having the uneven structure formed with the hole transport layer 103. Therefore, it is possible to easily make the hole transport layer 103 with the uneven patterned surface, the electron transport layer 105 with the uneven patterned surface, and the photoelectric conversion layer 106 intervening therebetween, at less cost.

In addition, it is also possible to compulsorily make uneven portions, as an electron transport path, using an imprint process.

### (First Modification)

In the above-described embodiment, the electron transport layer 105 and the photoelectric conversion layer 106 are simultaneously molded using the template with the uneven structure formed with the hole transport layer 103. However, the electron transport layer 105 may be molded by forming the photoelectric conversion layer 106 on the uneven patterned surface of the hole transport layer 103, and using the template with the uneven structure formed with the hole transport layer 103 and the photoelectric conversion layer 106.

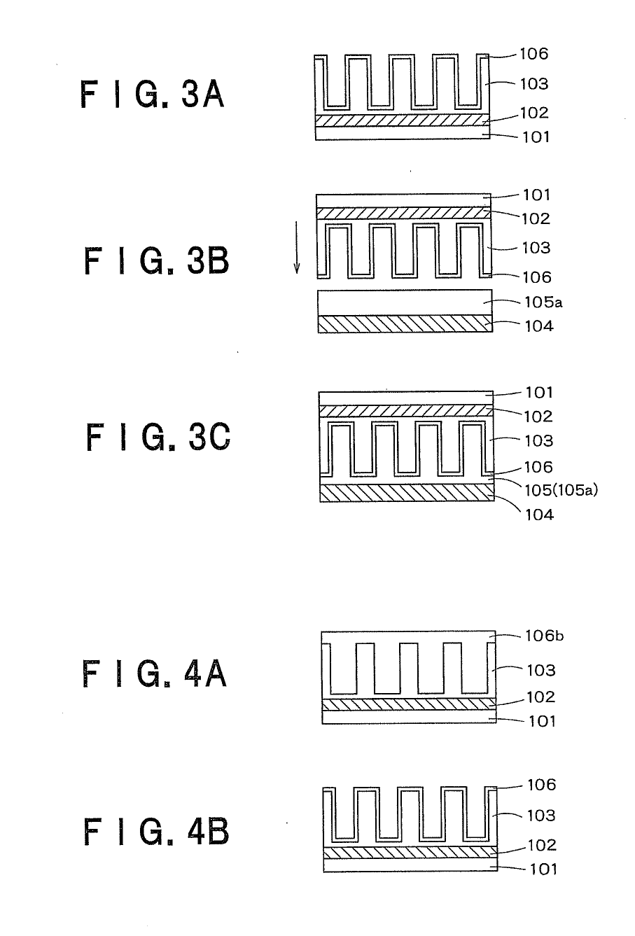

For example, as illustrated in FIG. 2B, after the hole transport layer 103 is formed, a photoelectric conversional layer formation material is formed on the uneven patterned surface of the hole transport layer 103 using an ALD (Atomic Layer Deposition) technique, thereby forming the photoelectric conversion layer 106, as illustrated in FIG. 3A.

As illustrated in FIG. 3B, a laminated body composed of the glass substrate 101, the transparent electrode 102, the hole transport layer 103, and the photoelectric conversion layer 106 is brought into contact with a laminated body composed of the metal electrode 104 and the electron transport layer formation material 105a.

As illustrated in FIG. 3C, the electron transport layer formation material 105a goes into the uneven pattern of the hole transport layer 103 and the photoelectric conversion layer 106. After the uneven pattern is filled with the electron transport layer formation material 105a, light irradiation or heating is performed to harden the electro transport layer formation material 105a.

According to this method, it is also possible to produce an organic thin film solar cell in which the photoelectric conversion layer 106 is provided between the uneven patterned surface of the hole transport layer 103 and the uneven patterned surface of the electron transport layer 105. The production cost according to this method is larger than that of the production method according to the above-described embodiment. However, the photoelectric conversion layer 106 can securely be formed between the uneven patterned surface of the hole transport layer 103 and the uneven patterned surface of the electron transport layer 105.

A filler agent where the volume shrinks after application may be used as the photoelectric conversion layer formation material to form the photoelectric conversion layer 106 on the surface of the hole transport layer 103. For example, as illustrated in FIG. 4A, a filler agent 106b covers the hole transport layer 103 in such a manner that the uneven pattern is filled with the agent. Subsequently, as illustrated in FIG. 4B, the volume of the filler agent 106 shrinks, thereby forming the photoelectric conversion layer 106 on the surface of the hole transport layer 103.

### (Second Modification)

In the above-described embodiment, the hole transport layer 103 is molded using the template 110. However, both of the hole transport layer 103 and the photoelectric conversion layer 106 may simultaneously be molded using the template 110.

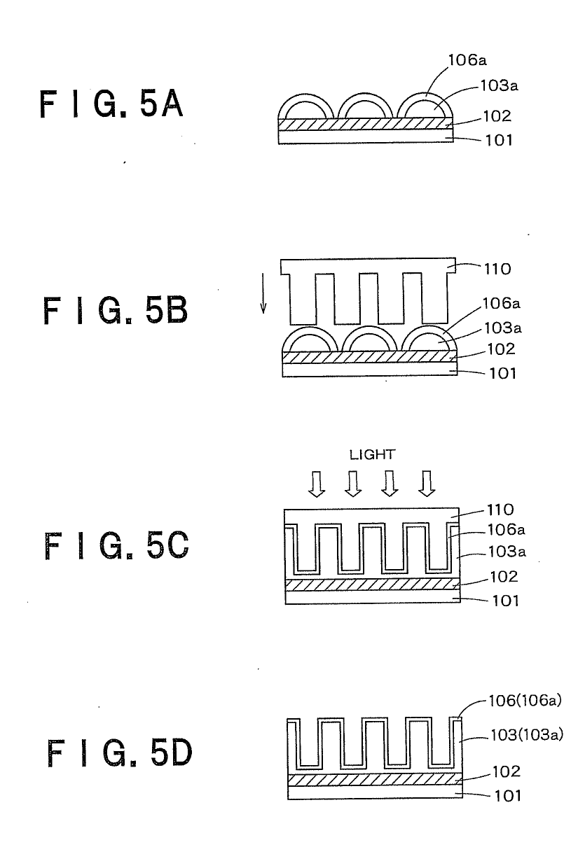

For example, as illustrated in FIG. 1A, after the transparent electrode 102 is formed on the glass substrate 101, the liquid hole transport layer formation material 103a is applied on the transparent electrode 102 as illustrated in FIG. 5A. At this time, it is adjusted that the photoelectric conversion layer formation material 106a is thinly located on the surface of the hole transport layer formation material 103a.

As illustrated in FIG. 5B, the template 110 with the uneven pattern is brought into contact with the photoelectric conversion layer formation material 106a and the hole transport layer formation material 103a.

When the template 110 is brought into contact with the photoelectric conversion layer formation material 106a and the hole transport layer formation material 103a, the photoelectric conversion layer formation material 106a and the hole transport layer formation material 103a go into the uneven pattern of the template 110, as illustrated in FIG. 5C. After the uneven pattern is filled with the photoelectric conversion layer formation material 106a and the hole transport layer formation material 103a, incident light (UV light) is applied to harden the photoelectric conversion layer formation material 106a and the hole transport layer formation material 103a.

As illustrated in FIG. 5D, the template 110 is separated from the photoelectric conversion layer formation material 106a and the hole transport layer formation material 103a. In this state, the photoelectric conversion layer formation material 106a and the hole transport layer formation material 103a have already been hardened, thus maintaining the state (form) in which the template 110 has come into contact therewith. This results in forming the hole transport layer 103 with the uneven patterned surface and the photoelectric conversion layer 106 formed on the hole transport layer 103.

After the formation of the layers, according to the same method as the first modification, it is possible to produce an organic thin film solar cell in which the photoelectric conversion layer 106 is formed between the uneven patterned surface of the hole transport layer 103 and the uneven patterned surface of the electron transport layer 105. According to this method, it is also possible to easily make the hole transport layer 103 and the electron transport layer 105 with the uneven patterned surface and the photoelectric conversion layer 106 located therebetween, at less cost.

### (Third Modification)

The photoelectric conversion layer 106 may be formed after the uneven patterned surface of the hole transport layer 103 and the uneven patterned surface of the electron transport layer 105 are formed.

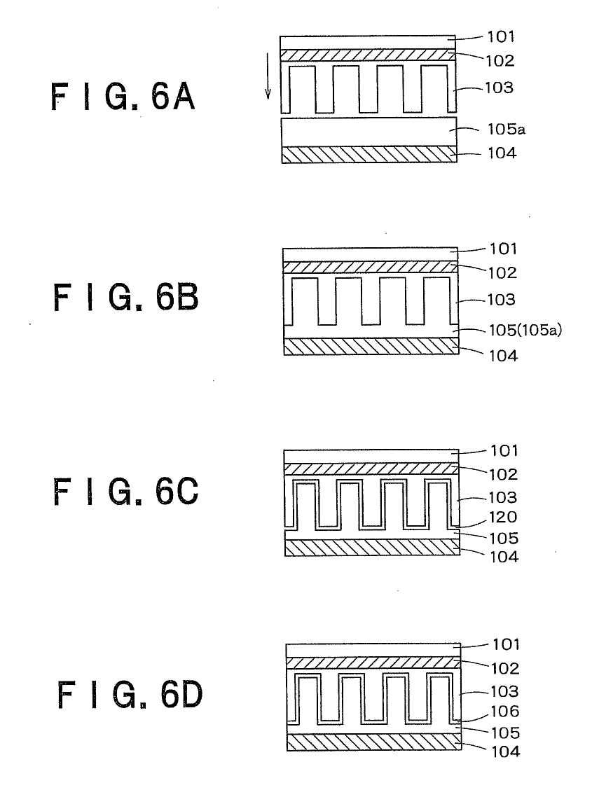

For example, as illustrated in FIG. 2B, after the hole transport layer 103 is formed, a laminated body composed of the glass substrate 101, the transparent electrode 102, and the hole transport layer 103 is brought into contact with a laminated body composed of the metal electrode 104 and the electron transport layer formation material 105a, as illustrated in FIG. 6A.

As illustrated in FIG. 6B, the electron transport layer formation material 105a goes into the uneven pattern of the hole transport layer 103. After the uneven pattern is filled with the electron transport layer formation material 105a, light irradiation or heating is performed to harden the electron transport layer formation material 105a. This results in forming the electron transport layer 105 having the uneven patterned surface.

As illustrated in FIG. 6C, a space 120 is formed between the hole transport layer 103 and the electro transport layer 105. For example, the space 120 can be formed by hardening and shrinking at least either one of the hole transport layer 103 and the electron transport layer 105.

As illustrated in FIG. 6D, the space 120 is filled with the photoelectric conversion layer formation material by the capillary pressure, thereby forming the photoelectric conversion layer 106. According to this method, it is also possible to produce an organic thin film solar cell in which the photoelectric conversion layer 106 is formed between the uneven patterned surface of the hole transport layer 103 and the uneven patterned surface of the electron transport layer 105.

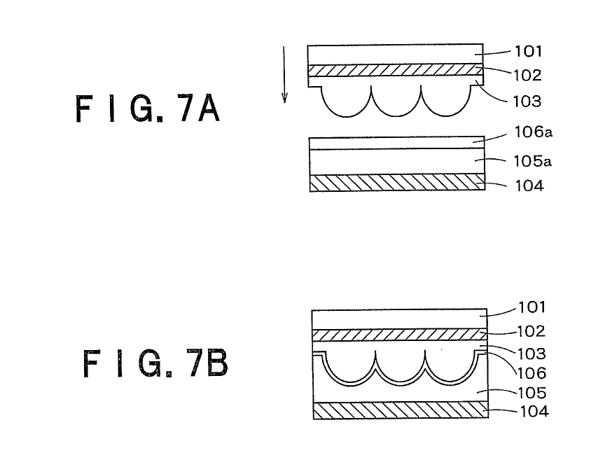

In the above-described embodiment and modifications, the hole transport layer 103 molded with the template 110 may be rounded as illustrated in FIG. 7A. In other words, the hole transport layer 103 may have a semielliptical cross section. When the hole transport layer 103 has such a shape, it is possible to restrain the variation of film thickness of the photoelectric conversion layer 106 as illustrated in FIG. 7B when both of the electron transport layer 105 and the photoelectric conversion layer 106 are simultaneously molded.

In the above-described embodiment and modifications, the hole transport layer 103 is molded with the template 110, and then, the electron transport layer 105 is molded with the hole transport layer 103 as a template. On the contrary, the electron transport layer 105 may be molded with the template 110 first, and then, the hole transport layer 103 may be molded with the electron transport layer 105 as a template.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing an organic thin film solar cell, comprising:
forming, on a first electrode, a first transport layer having an uneven pattern and a photoelectric conversion layer provided on a surface of the uneven pattern;
forming a second transport layer on a second electrode; and
bringing the uneven pattern having the photoelectric conversion layer is formed thereon into contact with the second transport layer to mold the second transport layer.

2. The method of manufacturing an organic thin film solar cell, according to claim 1, wherein the first transport layer having the uneven pattern is formed on the first electrode, and the photoelectric conversion layer is formed on the surface of the uneven pattern, using an ALD technique.

3. The method of manufacturing an organic thin film solar cell, according to claim 1, wherein the first transport layer having the uneven pattern is formed on the first electrode, a photoelectric conversion layer formation material is applied to cover the uneven pattern, and the photoelectric conversion layer formation material is shrunk in volume to form the photoelectric conversion layer.

4. The method of manufacturing an organic thin film solar cell, according to claim 1, further comprising:
applying a first transport layer formation material on the first electrode;
applying a photoelectric conversion layer formation material on a surface of the first transport layer formation material;
bringing a template having a pattern corresponding to the uneven pattern into contact with the first transport layer formation material and the photoelectric conversion formation material; and
hardening the first transport layer formation material and the photoelectric conversion layer formation material, in a state where the template is brought into contact therewith, thereby forming the first transport layer and the photoelectric conversion layer.

5. The method of manufacturing an organic thin film solar cell, according to claim 1, wherein the uneven pattern has a semielliptical cross section.

6. A method of manufacturing an organic thin film solar cell, comprising:
forming a first transport layer having an uneven pattern on a first electrode;
forming a second transport layer formation material and a photoelectric conversion layer formation material on a second electrode; and
bringing the uneven pattern into contact with the second transport layer formation material and the photoelectric conversion layer formation material, and hardening the second transport layer formation material and the photoelectric conversion layer formation material, thereby forming a second transport layer and a photoelectric conversion layer.

7. The method of manufacturing an organic thin film solar cell, according to claim 6, wherein the uneven pattern has a semielliptical cross section.

8. A method of manufacturing an organic thin film solar cell, comprising:
forming a first transport layer having an uneven pattern on a first electrode;
forming a second transport layer formation material on a second electrode;
bringing the uneven pattern into contact with the second transport layer formation material, and hardening the second transport layer formation material, thereby forming a second transport layer; and
making a space between the first transport layer and the second transport layer, and forming a photoelectric conversion layer in the space.

9. The method of manufacturing an organic thin film solar cell, according to claim 8, wherein at least one of the first transport layer and the second transport layer is hardened and shrunk, thereby forming the space.

10. The method of manufacturing an organic thin film solar cell, according to claim 9, wherein the uneven pattern is a semielliptical cross section.
